(19) United States
(12) Patent Application Publication
(10) Pub. No.: US 2011/0109328 A1
(43) Pub. Date: May 12, 2011

(54) Flush-Mounted Capacitive Sensor Mount

(75) Inventor: Joel Gulbranson, Ham Lake, MN (US)

(73) Assignee: AGRICHEM, INC., Ham Lake, MN (US)

(21) Appl. No.: 12/984,171

(22) Filed: Jan. 4, 2011

Related U.S. Application Data
(63) Continuation of application No. 12/044,086, filed on Mar. 7, 2008, now abandoned.

(51) Int. Cl. G01R 27/26

(52) U.S. Cl. 324/664

(57) ABSTRACT

In some embodiments, a method of monitoring particulates may include one or more of the following steps: (a) receiving the particulates in a particulate flow restrictor, (b) collecting a particulate sample in a body section of the flow restrictor, (c) sensing moisture content of the particulate with a flush mounted capacitive sensor, (d) allowing the particulate to empty out of the flow restrictor through a narrowed opening in a discharge section of the flow restrictor, (e) concentrating the particulate sample at a sensor surface, (f) shielding the sensor from stray electric fields, and (g) inputting the particulate at the funnel opening of the flow restrictor.

### CROSS-REFERENCE TO RELATED APPLICATION

This application is a continuation of application Ser. No. 12/044,086, filed Mar. 7, 2008, and entitled “Flush-Mounted Capacitive Sensor Mount”.

### I. FIELD OF THE INVENTION

Embodiments of the present invention generally relate to sensors. Particularly, embodiments of the present invention relate to capacitive sensors. More particularly, embodiments of the present invention relate to capacitive sensors for measuring dielectric properties such as moisture, density and/or detecting the presence or proximity of an object.

### II. BACKGROUND

Moisture monitoring and control are extremely important in processing many particulate materials ranging from feed grain to coal to kitty litter. Too much moisture can create problems with spoilage and flow characteristics. Too little moisture frequently results in dusty conditions in the processing area. If the low moisture content is caused by over-drying during processing, it means energy has been wasted to produce an inferior, dusty product. If the product is a food or feed material, over-drying can damage flavor, aroma, and nutrient availability.

Moisture analysis covers a variety of methods for measuring moisture content in both high level and trace amounts in solids, liquids, or gases. Moisture in percentage amounts is monitored as a specification in commercial food and feed production. There are many applications where trace moisture measurements are necessary for manufacturing and process quality assurance.

The standard reference laboratory method for measuring high level moisture content in solid or semi-solid materials is loss on drying (LOD). In this technique a sample of material is taken from the process, weighed, heated in an oven for a specified period, cooled in the dry atmosphere of a desiccator, and then reweighed. If the volatile content of the solid is primarily water, the LOD technique gives a good measure of moisture content. Because the manual laboratory method generally requires several hours, automated moisture analyzers have been developed to reduce the time necessary for an assay to just a few minutes. Even these devices require a sample to be removed from a particulate process stream for the moisture assay and are of limited use for on-line moisture monitoring and process control systems required for optimum energy use and finished product quality.

Capacitance sensors excel in sensing the presence of a wide variety of solids, aqueous and organic liquids, and slurries. The technique is frequently referred to as RF for the radio frequency signals generated by the capacitance circuit. The sensors can be designed to sense material with dielectric constants as low as 1.1 (coke and fly ash) and as high as 88 (water) or more. Sludges and slurries such as dehydrated cake and sewage slurry (dielectric constant—50) and liquid chemicals such as quicklime (dielectric constant—90) can also be sensed. Dual-probe capacitance level sensors can also be used to sense the interface between two immiscible liquids with substantially different dielectric constants.

Capacitance sensors require phase modulation and the use of higher frequencies to make the sensor suitable for applications in which dielectric constants are similar. The sensor contains no moving parts, is rugged, simple to use, easy to clean, and can be designed for high temperature and pressure applications.

Appropriate choice of sensor components reduces or eliminates problems caused by abrasion and corrosion. Point level sensing of adhesives and high-viscosity materials such as oil and grease can result in the build up of material on the probe; however, this can be minimized by using a self-tuning sensor. For liquids prone to foaming and applications prone to splashing or turbulence, capacitance level sensors can be designed with splashguards or stilling wells, among other devices.

A significant limitation for capacitance probes is in tall bins used for storing bulk solids. The requirement for a conductive probe extending to the bottom of the measured range is problematic. Long conductive cable probes (20 to 50 meters long) suspended into the bin or silo, are subject to tremendous mechanical tension due to the weight of the bulk powder in the silo and the friction applied to the cable. Such installations will frequently result in a cable breakage.

Most capacitive sensors for measuring material properties use a parallel plate or concentric cylinder design. The sensors work well in the laboratory or in a continuous stream of material, but certain applications require a less obtrusive sensor. Proximity sensors may be used to measure the dielectric properties of an object without entering or penetrating the object.

Proximity detectors typically measure capacitance between one conductor and ground and detect the presence of an object by noting the change in sensor capacitance when the object comes within the electric field generated between the sensor and a reference potential. To measure in only one direction, such a sensor will typically be shielded on one side with a reference potential. This prevents observing objects on the shielded side but introduces a large measured capacitance which diminishes the sensitivity of the sensor.

Attempts have been made to develop a capacitive sensor having a field which extends in one direction without diminishing sensitivity. A capacitive proximity sensing element which is backed by a reflector driver at the same voltage as the sensor is known. This results in an effective shield not increasing the measured capacitance. Regardless, complex circuitry is required to drive the shield.

Capacitive moisture sensors have been shown to be rugged, reliable, and economical as laboratory or desk-top instruments and are widely used in the grain industry. Since their signals are affected by moisture content, density, and temperature of the particulate sample, controlling sample density and accurately measuring temperature are essential for an accurate moisture assay. Controlling density of a flowing particulate material in an on-line industrial setting has been a very difficult problem not previously solved.

It would be desirable for a capacitive on-line process sensor to also be rugged, reliable, and economical. Further, it would be desirable for such a capacitive sensor to control sample density and accurately measure temperature.

### SUMMARY OF THE INVENTION

In some embodiments, a flow restrictor may include one or more of the following features: (a) a receiver section coupled to a body section, (b) a discharge section coupled to the body section, (c) a capacitive sensor coupled to the body section, (d) a flared opening on the receiver section, and (e) a reduced opening on the discharge section.

In some embodiments, a method of manufacturing a flow restrictor may include one or more of the following steps: (a) forming integrally a receiver section, a body section, and a discharge section, (b) coupling a capacitive sensor to the body section, (c) forming a flare in the receiver section for receiving particulate, (d) forming mounting holes in the body section for coupling the capacitive sensor to the body section with fasteners, and (e) forming the capacitive sensor from a dielectric substrate having a planar configuration with a pair of sensing electrodes arranged on one surface of said substrate in spaced relation, and a shielding electrode being grounded and arranged between and parallel to said pair of sensing electrodes.

In some embodiments, a method of monitoring particulates may include one or more of the following steps: (a) receiving the particulates in a particulate flow restrictor, (b) collecting a particulate sample in a body section of the flow restrictor, (c) sensing moisture content of the particulate with a flush mounted capacitive sensor, (d) allowing the particulate to empty out of the flow restrictor through a narrowed opening in a discharge section of the flow restrictor, (e) concentrating the particulate sample at a sensor surface, (f) shielding the sensor from stray electric fields, and (g) inputting the particulate at the funnel opening of the flow restrictor.

### DESCRIPTION OF THE DRAWINGS

FIG. 1 shows a diagrammatic figure of an elevator which can be uses in embodiments of the present invention;

FIG. 2 shows a diagrammatic figure of a material transportation system in an embodiment of the present invention;

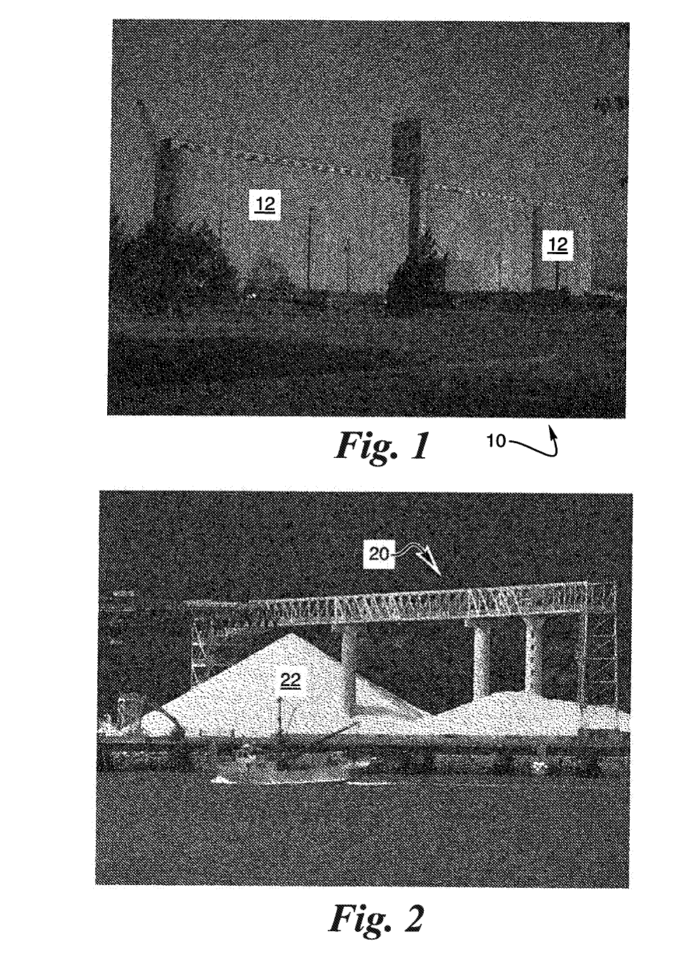

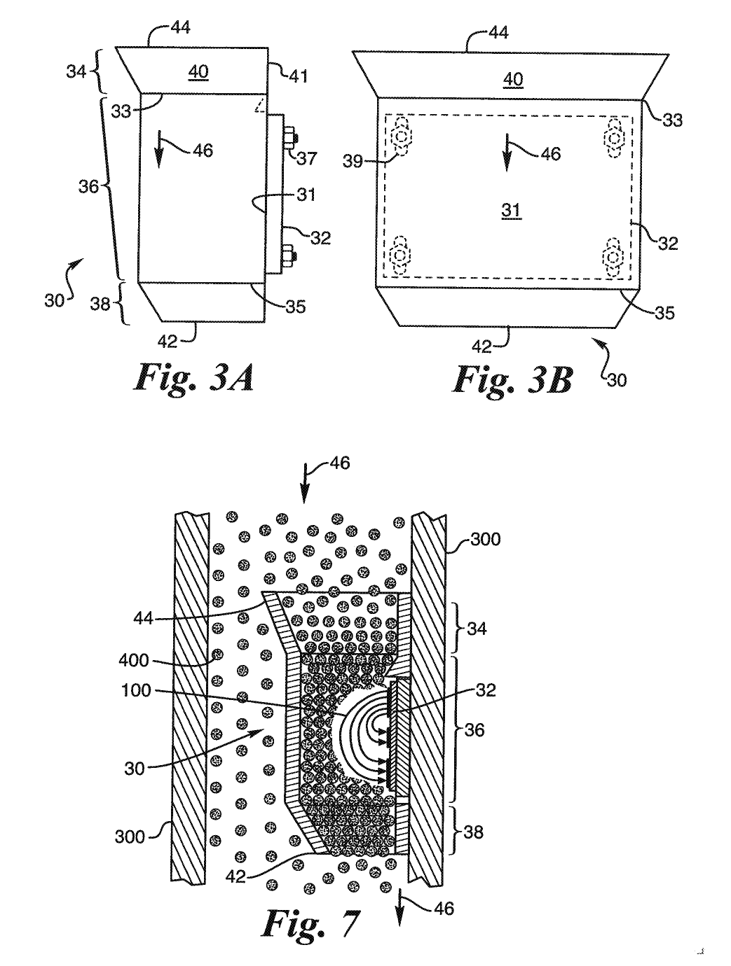

FIG. 1A shows a side view of a flush-mounted capacitive sensor mount in an embodiment of the present invention;

FIG. 1B shows a front view of a flush-mounted capacitive sensor mount in an embodiment of the present invention;

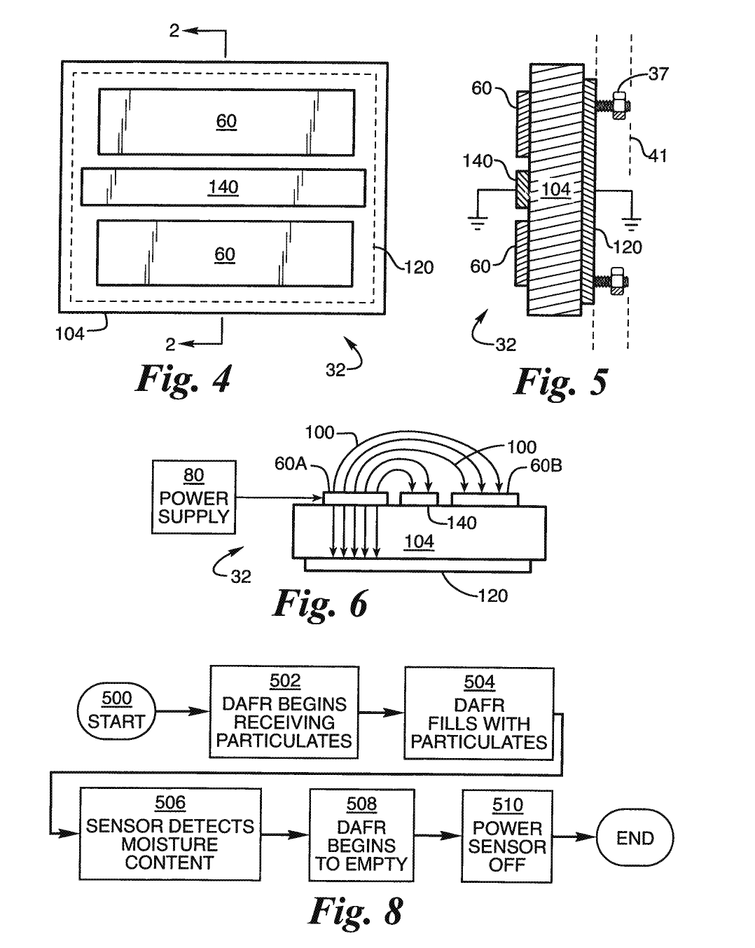

FIG. 2 is a front plan view of a capacitive sensor element according to an embodiment of the invention;

FIG. 3 is a sectional view of a sensor element taken along line 2-2 of FIG. 4;

FIG. 4 is a side plan view of a sensor element of showing an electric field generated by sensing electrodes in an embodiment of the present invention;

FIG. 5 is an elevated side profile of a flush-mounted capacitive sensor mount in an embodiment of the present invention; and

FIG. 6 is a flow process diagram of a method of sensing moisture in flowing particulate in an embodiment of the present invention.

### DESCRIPTION OF THE PREFERRED EMBODIMENT

The following discussion is presented to enable a person skilled in the art to make and use the present teachings. Various modifications to the illustrated embodiments will be readily apparent to those skilled in the art, and the generic principles herein may be applied to other embodiments and applications without departing from the present teachings. Thus, the present teachings are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of the present teachings. Skilled artisans will recognize the examples provided herein have many useful alternatives and fall within the scope of the present teachings. While embodiments of the invention discussed below are discussed in detail with respect to moisture detection and control, it is fully contemplated embodiments of this invention could be extended to moisture detection and control for most any particulate, aggregate, or any material requiring moisture monitoring without departing from the spirit of the invention.

Drying is a mass transfer process resulting in the removal of water or another solvent, by evaporation from a solid, semi-solid, or liquid to produce a concentrated or solid state.

Hundreds of millions of tons of wheat, corn, soybean, rice, sorghum, sunflower seeds, rapeseed/canola, barley, oats, etc., are dried each year. Drying typically reduces moisture content from 17-30% (by weight) to values between 8 and 15% w/w, depending on the grain and its end use.

With reference to FIG. 1, a diagrammatic figure of an elevator for use of embodiments of the present invention is shown. Elevator 10 is a building or complex of buildings for storage and shipment of grain. Grain elevator bins, tanks, and silos 12 can be constructed of steel or reinforced concrete. Bucket elevators are used to lift grain to a distributor or consignor where it flows by gravity through spouts or conveyors and into one of a number of bins, silos, or tanks in a facility. When desired, the elevator's silos, bins, and tanks 12 are then emptied by gravity flow, sweep augers, and conveyors. As grain is emptied from the elevator's bins, tanks and silos 12 it is conveyed, blended and weighed into trucks, railroad cars, or barges and shipped to end users of grains (mills, ethanol plants, etc.)

With reference to FIG. 2, a diagrammatic figure of a material transportation system in an embodiment of the present invention is shown. A belt conveyor system 20 can consist of two or more pulleys, with a continuous loop of material—the conveyor belt—that rotates about them. One or both of the pulleys can be powered, moving the belt and the material on the belt forward. The powered pulley is called the drive pulley while the un-powered pulley is called the idler. There are two main industrial classes of belt conveyors; Those in general material handling such as those moving boxes along inside a factory and bulk material handling such as those used to transport industrial and agricultural materials, such as silicon 22, coal, ores, etc., generally in outdoor locations as shown in FIG. 2.

With reference to FIGS. 1A and 1B, views of a flush-mounted capacitive sensor mount in an embodiment of the present invention are shown. A defined area flow restrictor (DAFR) 30 can be designed to collect and concentrate flowing particulate materials. It is understood for the discussion of this invention, particulate can be most any material such as sand, coal, grain, kitty litter, or silicon 22 without limitation to these examples given and without departing from the spirit of the invention. This can provide a constant reproducible physical and electric field environment for a flush-mounted capacitive moisture sensor 32, as will be described in more detail below.

DAFR 30 can be designed to be mounted in a location such as a chute, downspout, or at the discharge from conveyances such as belt, bucket, or screw conveyors where particulate materials are flowing by gravity and subject to having variable volumes and densities. DAFR 30 continuously collects a proportional sample from the particulate flow, concentrates it at a sensor surface 31 and provides a reproducible sample volume and density.

DAFR 30 can also shield sensor 32 from stray electric fields possibly present in particulate processing facility 10 and isolate sensor 32 from potential grounding effects of nearby equipment or structures.

DAFR 30 can have three body sections. A receiver section 34, a body section 36, and a discharge section 38. Overall DAFR can be 10.37 inches in height by 10.90 inches in width. Receiver section 34 has an opening 40 located at body section end 33 with a flare 44 having a width reducing from 10.90 inches to 7.90 inches to funnel particulate into body section 36. Receiving section flare 44, having flat backside 41, funnels particulate into body section 36 to keep body section 36 filled with particulate. Thus, assisting in concentrating the particulate into a central location, body section 36, to be monitored. Discharge section 38 has an opening 42 located at body section end 35 with a width reducing from 7.90 inches to 5.74 inches. This width reduction provides flow restriction at discharge section 38 to provide a consistent reproducible particulate density in body section 36 by restricting flow of particulate out of opening 42 causing particulate to back up and fill body section 36. DAFR 30 can be integrally formed of any material such as a plastic, fiberglass or metal. However, it is helpful if DAFR 30 is formed of a conductive composite material or metal to assist in electrically isolating sensor 32 from stray electromagnetic fields.

Sensor 32 has a surface area of 4.675 inches by 7.675 inches mounted with a long dimension perpendicular to a particulate flow direction shown by arrow 46. In an alternative embodiment sensor 32 could be mounted with the long dimension parallel to the particulate flow direction 46. It is noted the shape of DAFR 30 and orientation of sensor 32 can be dictated by the space available where DAFR 30 would be installed. It is further contemplated DAFR 30 and sensor 32 could have most any dimension without departing from the spirit of the invention. All DAFR 30 dimensions could be altered to physically fit a particular site and or particulate material having any unique physical and or chemical properties. One embodiment could include an adjustable gate at discharge section 38.

Sensor 32 is described with reference to FIGS. 2-4. Sensor 32 includes a substrate 104 formed of printed circuit board material and having a planar configuration. On one surface of substrate 104 is provided a spaced pair of sensing electrodes 60. Electrodes 60 are coplanar and can have a rectangular configuration. However, it will be appreciated by those of ordinary skill in the art other configurations (e.g., concentric rings) may be used for sensing electrodes 60 so long as they are spaced from one another. Sensing electrodes 60 are formed of a conductive material. Electrodes 60 can be formed of a copper film.

When alternating power is applied to the sensing electrodes 60A and 60B from a power supply 80, an electric field represented by lines 100 is generated between electrode 60A and electrode 60B. Collectively, lines 100 represent an electric field for sensing elements 60 as will be developed in greater detail below.

Two shield electrodes are also mounted on substrate 104, both shield electrodes being connected with a reference potential. First shield electrode 120 is arranged on the surface of substrate 104 opposite the surface on which sensing electrodes 60 are arranged. First shield electrode 120 has a configuration similar to but less than substrate 104 and is arranged parallel to sensing electrodes 60. Referring to FIG. 6, first shield electrode 120 intercepts or blocks electric field 100 from extending to the rear or opposite surface of sensing electrodes 60. Thus, sensor 32 only measures or detects objects within the 180° field on the sensing electrode side of the element. Interference from behind the element, e.g., the side on which first shield element 120 is arranged, is prevented.

A second shield electrode 140 is arranged on the front surface of dielectric substrate 104 between and co-planar with sensing electrodes 60 in spaced parallel relation. Second shield electrode 140 intercepts or blocks electric field 100 closest to the sensing element. This prevents the densest portion of electric field 100 very near the element from severely dominating capacitive measurements.

If desired, a protective dielectric layer can be provided over sensing electrodes 60, second shield electrode 140, and the remainder of the one surface of dielectric substrate 104.

The useful electric field 100 originates in sensing electrode 60A and terminates in sensing electrode 60B. This electric field 100 is forced outwardly into the object or material being sensed. As an object enters the useful electric field 100, the change in capacitance between the sensing electrodes 60 is detected (for proximity detectors) or measured (for content measuring devices). More particularly, the dielectric properties of a material or object are detected and measured. This is particularly useful for measuring properties such as moisture content of a particulate solid.

The shape and size of sensing electrodes 60 and shield electrodes 120 and 140 will determine the sensing range of the capacitive sensing element 32 according to embodiments of the invention. Larger sensing electrodes 60 spaced farther apart and wide coplanar shield electrodes 120 and 140 will provide more distant sensing, while smaller and more closely spaced electrodes will provide measurements closer to the element.

With reference to FIGS. 5 and 6, a method of sensing moisture in flowing particulate 400 in an embodiment of the present invention is shown. During operation of process 500, particulate 400 begins to flow into DAFR 30 at flare 44 of receiving section 34 at state 502. It is noted, DAFR 30 is flush mounted to chute 300. DAFR 30 is designed to collect and concentrate flowing particulate materials 400 to subject particulate 400 to a constant reproducible physical and electric field 100. DAFR 30 can be mounted to a chute 300 to receive particulate 400. DAFR 30 could also be mounted to the discharge end of a belt, bucket, or screw conveyor to receive direct discharge (or flow through) of particulate 400.

Some particulate 400 will flow out through discharge end 38; however, due to discharge end 38 tapering to a narrow opening 42 only a portion of particulate 400 entering DAFR 30 exits opening 42. Particulate 400 can be most any particulate such as corn, kitty litter, or coal and can be received by DAFR 30 by a mode such as chute 300 shown in FIG. 7. Therefore, DAFR 30 begins to fill with particulate 400 at state 504. DAFR 30 continuously collects a proportional sample from particulate flow, concentrates it in body 36 directly in front of sensor 32 thus providing a constantly moving, but reproducible sample volume and density for sensor 32. Sensor 32; held in place by fasteners 37 at mounting holes 39, can now begin the process of detecting a particulate 400 and/or detecting moisture content of particulate 400 at state 506.

DAFR 30 shields sensor 32 from stray electric fields 100 present in the particulate processing facility and isolates it from potential grounding effects of nearby equipment or structures. This is due to DAFR's 30 metal construction which absorbs stray electric fields 100 present and routes these signals to ground; however, as discussed above, DAFR 30 can be constructed from most any type of conductive material.

After all particulate 400 has stopped entering DAFR 30, DAFR 30 begins to empty at state 508. At state 510, sensor 32 can be powered off and moisture detection process 500 can be complete.

Thus, embodiments of the FLUSH-MOUNTED CAPACITIVE SENSOR MOUNT are disclosed. One skilled in the art will appreciate the present teachings can be practiced with embodiments other than those disclosed. The disclosed embodiments are presented for purposes of illustration and not limitation, and the present teachings are limited only by the claims follow.

1-20. (canceled)

21. A moisture monitoring apparatus for particulate material flowing through a conduit, comprising:
(a) a sampling chamber adapted to be disposed in a conduit through which particulate material is made to flow, the sampling chamber having an inlet end, an outlet end and at least one planar wall surface;
(b) a generally flat capacitive sensing element affixed to the planar wall and exposed to particulate material flowing through the sampling chamber, the capacitive sensing element comprising a planar electrically insulating substrate having first and second major surfaces with a pair of spaced-apart, parallel conductive strips on the first major surface and a continuous conductive sheet on the second major surface;
(c) a source of alternating current of a predetermined frequency coupled to one of the pair of parallel conductors; and
(d) means for measuring variations in capacitive reactance of the sensor due to changes in moisture content of the particulate material.

22. The moisture monitoring apparatus of claim 21 and further including a third conductive strip on the first major surface situated between the pair of conductive strips and where the third conductive strip and the conductive sheet are adapted to be connected to a source of reference potential.

23. The moisture monitoring apparatus of claim 21 wherein the sampling chamber comprises a tubular body having an outward taper at the inlet end and an inward taper at the outlet end.

24. The moisture monitoring apparatus of claim 22 and further including a protective dielectric layer covering the pair of conductive strips and the third conductive strip on the first major surface.

25. The moisture monitoring apparatus of claim 24 wherein the capacitive sensing element is affixed with bolts to said planar wall.

26. The moisture monitoring apparatus of claim 21 wherein the sampling chamber is made from a conductive material that serves to shield the sensing element from exposure to stray electric fields.

27. A method of monitoring the moisture content of particulate material while flowing through a conduit comprising the steps of:
(a) placing the sampling chamber of claim 21 within the conduit to intercept a substantially constant volume of a portion of the particular material flowing through the conduit; and
(b) sensing changes in the capacitance between the pair of conductive strips due to moisture induced changes in the dielectric constant of the particulate material flowing through the conduit.

28. A method of monitoring the moisture content of particulate material while flowing through a conduit comprising the steps of:
(a) placing the sampling chamber of claim 22 within the conduit to intercept a substantially constant volume of a portion of the particular material flowing through the conduit; and
(b) sensing changes in the capacitance between the pair of conductive strips due to moisture induced changes in the dielectric constant of the particulate material flowing through the conduit.

29. A method of monitoring the moisture content of particulate material while flowing through a conduit comprising the steps of:
(a) placing the sampling chamber of claim 23 within the conduit to intercept a substantially constant volume of a portion of the particular material flowing through the conduit; and
(b) sensing changes in the capacitance between the pair of conductive strips due to moisture induced changes in the dielectric constant of the particulate material flowing through the conduit.

30. A method of monitoring the moisture content of particulate material while flowing through a conduit comprising the steps of:
(a) placing the sampling chamber of claim 24 within the conduit to intercept a substantially constant volume of a portion of the particular material flowing through the conduit; and
(b) sensing changes in the capacitance between the pair of conductive strips due to moisture induced changes in the dielectric constant of the particulate material flowing through the conduit.
